(19) United States
(12) Patent Application Publication
(10) Pub. No.: US 2013/0335094 A1
(43) Pub. Date: Dec. 19, 2013

(54) VIBRATORY ANALYSIS OF BATTERIES

(71) Applicants: Douglas E. Adams, West Lafayette, IN (US); James Caruthers, Lafayette, IN (US); Farshid Sadeghi, West Lafayette, IN (US); Mark Suchomel, West Lafayette, IN (US); Nathan Sharp, West Lafayette, IN (US); Anand David, West Lafayette, IN (US)

(72) Inventors: Douglas E. Adams, West Lafayette, IN (US); James Caruthers, Lafayette, IN (US); Farshid Sadeghi, West Lafayette, IN (US); Mark Suchomel, West Lafayette, IN (US); Nathan Sharp, West Lafayette, IN (US); Anand David, West Lafayette, IN (US)

(73) Assignee: PURDUE RESEARCH FOUNDATION, West Lafayette, IN (US)

(21) Appl. No.: 14/001,330

(22) PCT Filed: Feb. 23, 2012
(86) PCT No.: PCT/US12/26351

§ 371 Date: Aug. 23, 2013

(30) Foreign Application Priority Data
Feb. 23, 2011 (US) 61445786

(51) Int. Cl. G01R 31/36

(52) U.S. Cl. CPC G01R 31/3634
USPC 324/426

(57) ABSTRACT

Methods and apparatuses for determining the charge of a battery are disclosed. Embodiments include determining the charge in batteries that exhibit mass diffusion during charging or discharging, such as by evaluating the response of the battery to vibration. Alternate embodiments include evaluating the amplitude response of the battery and the phase shift response of the battery. Still other embodiment include evaluating the H₁₁ response of the battery to vibration. Further embodiment include vibrating the battery, for example, with a chirp frequency that may be in the acoustic range. Still further embodiments include performing a Fourier analysis of the battery response to vibration.

This application claims the benefit of U.S. Provisional Application No. 61/445,786, filed Feb. 23, 2011, the entirety of which is hereby incorporated herein by reference.

### FIELD

Various embodiments of the present invention pertain to methods and apparatuses for analyzing objects in which there are mass diffusion, and some embodiments in particular pertain to analysis of the state of charge of certain types of batteries.

### BACKGROUND

The electrode material of certain types of batteries, such as lithium-ion batteries, are intercalated materials. These types of batteries (which include lithium-ion batteries) operate by shuttling lithium cations reversibly between the anode and cathode electrodes. During battery discharge, lithium ions leave (de-intercalate) the anode material and transfer (through diffusion, migration and convection) to the cathode where they are electrochemically insert (intercalate). The cations transfer back to the anode in the reverse process during battery charge. A schematic of this process is shown in FIG. 1. The battery's state of charge is defined by the remaining energy capacity relative to a maximum based on cell manufacturing and design. However, cell capacity is highly dependent on the rate at which the battery is charged and discharged. The most common method to determine the state of charge of the battery is to measure the terminal voltage. However, FIG. 2 illustrates that changes in the voltage versus time in the discharge process are subtle. A small error in voltage measurement results in a great uncertainty in the actual remaining capacity. This uncertainty can result in a relatively rapid, unsafe and unexpected discharge of the battery.

### SUMMARY

Embodiments of the present invention provide an improved methods and apparatuses for vibratory analysis of a battery, for example, improved methods and apparatuses for analyzing the state of charge of a battery.

In accordance with a first aspect of embodiments of the present invention, battery charge is determined by evaluating the response (for example, the frequency response) of the battery to vibration. The battery may be of the type that exhibits mass diffusion during charging or discharging.

In accordance with alternate aspects of embodiments of the present invention the amplitude response and/or the phase response of the battery to vibration is evaluated. The analysis may include evaluating the H₁ or H₁₁ response of the battery to vibration.

Still other aspects of embodiment include actively vibrating the battery, for example, with a chirp frequency that may be in the acoustic range. Other aspects of embodiments include performing a Fourier analysis of the battery response to vibration.

This summary is provided to introduce a selection of the concepts that are described in further detail in the detailed description and drawings contained herein. This summary is not intended to identify any primary or essential features of the claimed subject matter. Some or all of the described features may be present in the corresponding independent or dependent claims, but should not be construed to be a limitation unless expressly recited in a particular claim. Each embodiment described herein is not necessarily intended to address every object described herein, and each embodiment does not necessarily include each feature described. Other forms, embodiments, objects, advantages, benefits, features, and aspects of the present invention will become apparent to one of skill in the art from the detailed description and drawings contained herein. Moreover, the various apparatuses and methods described in this summary section, as well as elsewhere in this application, can be expressed as a large number of different combinations and subcombinations. All such useful, novel, and inventive combinations and subcombinations are contemplated herein, it being recognized that the explicit expression of each of these combinations is unnecessary.

### BRIEF DESCRIPTION OF THE DRAWINGS

Some of the figures shown herein may include dimensions or may have been created from scaled drawings. However, such dimensions, or the relative scaling within a figure, are by way of example, and not to be construed as limiting.

FIG. 1 is a schematic representation of lithium-ion battery construction indicating transfer of ions during operation.

FIG. 2 is a graphical representation of change in voltage with time indicating that the state of charge is uncertain in at least the center portion of the curve.

FIG. 3 is a photograph showing lithium-ion battery cells undergoing tests with teardrop accelerometers on top faces along with stack actuators to measure acceleration spectrum during a sweep of vibration from, for example, 1 to 5000 Hz.

FIG. 4 shows the measured acceleration as a function of time for a sample test. The solid nature of the plot is due to the high frequency data sampling. The square indicates the area from which FIG. 5 is taken.

FIG. 5 shows a closer view of the square section shown in FIG. 4 indicating the presence of data points.

FIG. 6 is a graphical representation of the absolute value of the frequency response (H₁₁ Response) plotted against frequency. This response can be used to compare different states of charge and is typically more sensitive than terminal voltage.

FIG. 7 is a graphical representation of the absolute value of H₁₁ Response vs. Frequency as a function of the battery state of charge according to one embodiment of the present invention.

FIG. 8 is a graphical representation of the absolute value of H₁₁ Frequency Response Estimator plotted against applied actuator frequency according to another embodiment of the present invention. The legend indicates the approximate level of charge, where 100 corresponds to 100% charged (4.2V) and 0 correspond to 0% charge (2.7V).

FIG. 9 is a close-up of a portion of FIG. 7 illustrating the magnitude of measured driving point response as a function of the charge state showing increasing charge from left to right.

FIG. 10 shows a close-up of a portion of FIG. 8, illustrating the shift in frequency response as a function of battery state of charge. The legend indicates the approximate level of charge, where 100 corresponds to 100% charged (4.2V) and 0 corresponds to 0% charge (2.7V).

FIG. 11 shows voltage response (lines, left scale) and peak frequency response (points, right scale) as a function of cell capacity, reflecting that the peak frequency can be more sensitive to the cell capacity than the terminal voltage.

FIG. 12 shows the remaining capacity as a function of largest peak frequency location from FIG. 10. The curve is a general response showing a correlation between frequency and capacity.

FIG. 13 is a graphical representation of the adjusted phase angle plots showing the effects of battery charge state. All plots pass through the arbitrary point of 1500 Hz and 360 deg phase angle.

FIG. 14 shows phase angle response corrected to the same phase angle as the initial measurement at full charge. The legend indicates the approximate level of charge, where 100 corresponds to 100% charged (4.2V) and 0 corresponds to 0% charge (2.7V).

FIG. 15 shows an enhanced view from FIG. 13 of the phase angle vs. frequency as a function of battery state of charge. The charge state increases with each curve from left to right.

FIG. 16 is a close-up of a portion of the corrected phase angle response of FIG. 14 illustrating the frequency shift resulting from the change in state of charge. The legend indicates the approximate level of charge, where 100 corresponds to 100% charged (4.2V) and 0 corresponds to 0% charge (2.7V).

FIG. 17 is a schematic representation of a system according to another embodiment of the present invention.

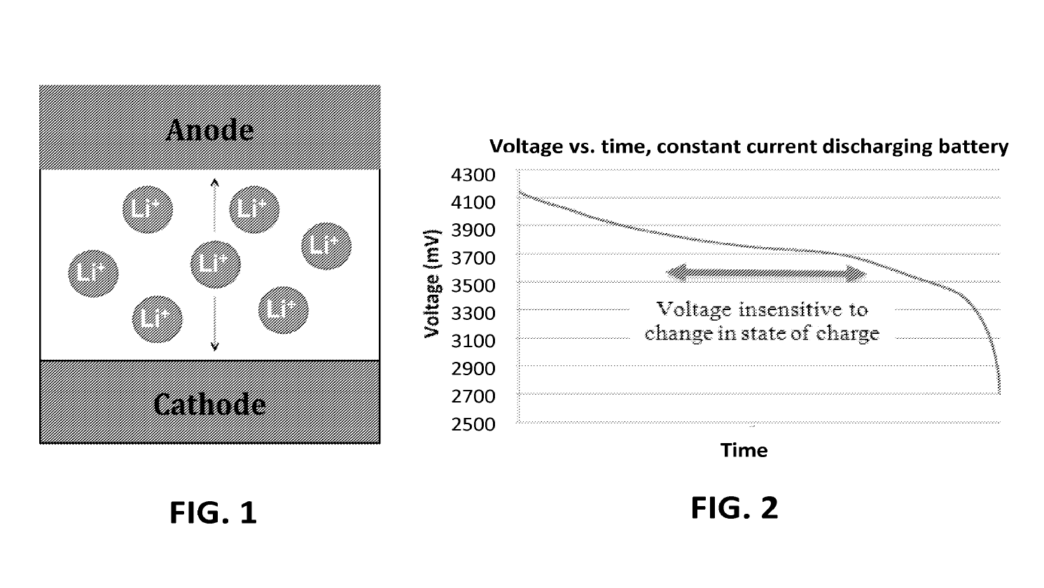

### DETAILED DESCRIPTION OF THE ILLUSTRATED EMBODIMENTS

For the purposes of promoting an understanding of the principles of the invention, reference will now be made to the embodiments illustrated in the drawings and specific language will be used to describe the same. It will nevertheless be understood that no limitation of the scope of the invention is thereby intended; any alterations and further modifications of the described or illustrated embodiments, and any further applications of the principles of the invention as illustrated herein are contemplated as would normally occur to one skilled in the art to which the invention relates. At least one embodiment of the invention is shown in great detail, although it will be apparent to those skilled in the relevant art that some features or some combinations of features may not be shown for the sake of clarity.

The use of an N-series prefix for an element number (NXX.XX) refers to an element that is the same as the non-prefixed element (XX.XX), except as shown and described thereafter. As an example, an element 1020.1 would be the same as element 20.1, except for those different features of element 1020.1 shown and described. Further, common elements and common features of related elements are drawn in the same manner in different figures, and/or use the same symbology in different figures. As such, it is not review to describe the features of 1020.1 and 20.1 that are the same, since these common features are apparent to a person of ordinary skill in the related field of technology.

Any reference to “invention” within this document is a reference to an embodiment of a family of inventions, with no single embodiment including features that are necessarily included in all embodiments, unless otherwise stated. Furthermore, although there may be references to “advantages” provided by some embodiments of the present invention, other embodiments may not include those same advantages, or may include different advantages. Any advantages described herein are not to be construed as limiting to any of the claims.

Specific quantities (spatial dimensions, temperatures, pressures, times, force, resistance, current, voltage, concentrations, wavelengths, frequencies, heat transfer coefficients, dimensionless parameters, etc.) may be used explicitly or implicitly herein, such specific quantities are presented as examples only and are approximate values unless otherwise indicated. Discussions pertaining to specific compositions of matter, if present, are presented as examples only and do not limit the applicability of other compositions of matter, especially other compositions of matter with similar properties, unless otherwise indicated.

Regardless of how the battery is used (cycled), the lithium distribution at a particular state of charge should be the same. Consequently, it is believed that measuring the physical structure inside the cell—looking at the actual chemistry and transfer of mass—is an accurate method of measuring the state of charge of a battery.

The lithium ions in lithium-ion batteries are generally less dense than the surrounding material. As lithium shuttles between the anode and cathode during the charge/discharge cycles, each electrode either intercalates and expands (increasing volume and decreasing density) or de-intercalates and contracts (decreasing volume and increasing density) as the lithium shuttles. Detecting the increases and decreases in volume of the electrode can provide a direct measurement of the cell's remaining capacity.

A transfer of mass also occurs, although this effect may be less pronounced than the change in volume. At the fully charged state, the anode contains more mass than the cathode, whereas the opposite is true for a fully discharged cell. Measuring the distribution of mass in the system can provide a direct measurement of the cell's remaining capacity.

Current battery monitoring techniques use three measurements (terminal voltage, current and temperature) and sophisticated algorithms to infer the remaining battery capacity. These are macroscopic measurements attempting to quantify a microscopic phenomenon. Embodiments of the present invention measure the state of charge of batteries that exhibit mass transfer during charging and discharging. Embodiments of the present invention measure the state of charge of batteries that exhibit mass diffusion during charging and discharging. Embodiments of the present invention measure the state of charge of lithium-ion batteries. Various embodiments disclosed herein directly measure vibrational aspects (such as peak response, phase shift, and/or mode shape) that respond to the mass diffusion. Embodiments of the present invention have applicability to determining the state of charge in batteries with electrode materials comprising intercalated metals, such as lithium-ion batteries. These various embodiments directly measure the phenomenon closely related to the charge distribution (e.g., the lithium distribution) in the cell, and hence the state of charge.

Various embodiments of the present invention pertain to the measurement of various effects that indicate a redistribution of mass within a battery cell. As one example, a shift in the distribution of mass within a cell can affect the dynamic response of the cell due to a vibratory excitation, the vibratory excitation potentially being generated either externally or internally. In some embodiments the change in mass distribution results in a change in one or more resonant frequencies of the battery structure. As yet another example, the variations in mass distribution are measured in other embodiments as a change in the phase angle response of the cell of the battery structure at one or more frequencies. In yet other embodiments, and especially in those in which there are multiple sensors, the variation in mass density may be detectable as variations in a mode shape, or more simplistically, in a comparison of the cell response characteristics at two different points.

As one example of the latter, as the battery changes its state of charge, there is a corresponding change in the mass distribution of the battery that can be thought of as: (a) one region of the battery becoming more dense; and (b) a different region of the battery becoming less dense. In some battery geometries, and especially in those embodiments in which the sensors are embedded within the battery such that one sensor is adjacent to an anode and another sensor is adjacent to a cathode, it may be possible to measure internal structural responses that correlate to one of the locations becoming more dense and the other location becoming less dense. In some embodiments, the calculation of battery charge may be related to a first vibratory phenomenon in the more dense area as compared to a second, different vibratory phenomenon in the less dense area.

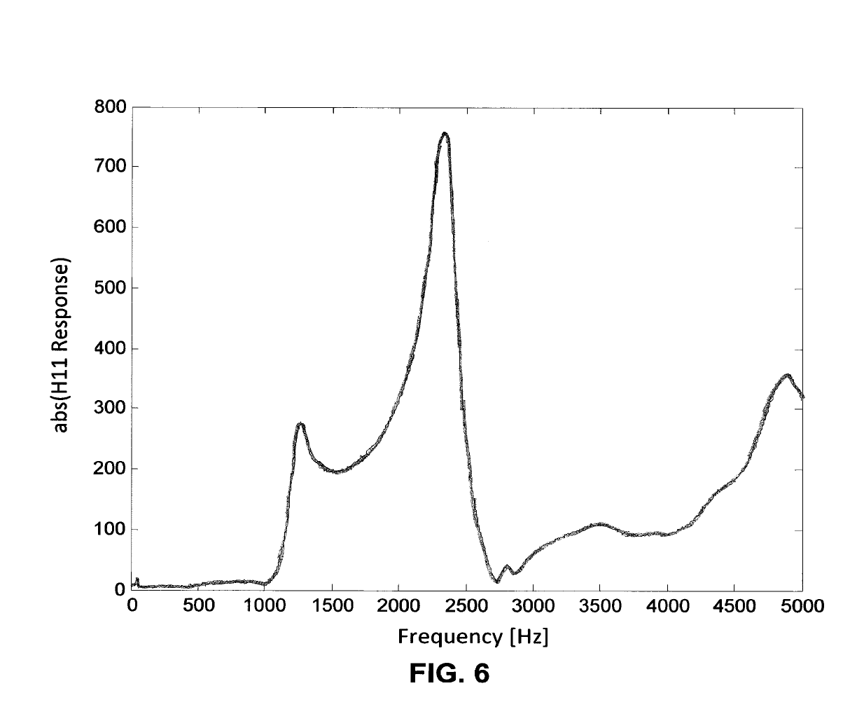

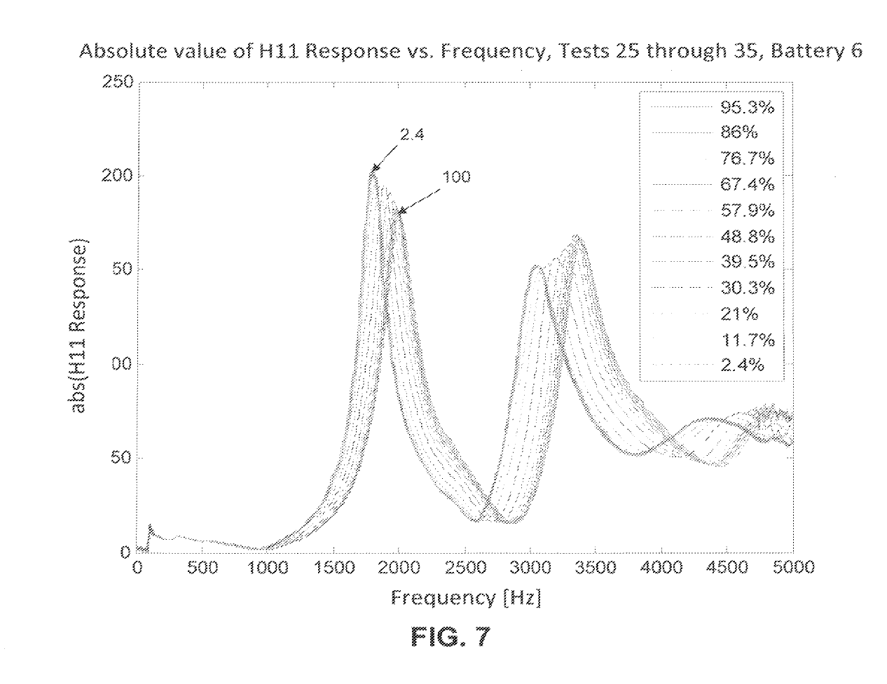

It has been found in several different tests that the method of testing can be varied to show the effect of battery charge on vibrational characteristics in different ways. As one example, one test showed an increase in peak vibrational response as the battery charge was increased. In yet another test, the peak measured amplitudes showed a decrease as the charge of the battery increased. Further, in one of the tests a resonant mode was detected changing from about 1700 Hz to about 2000 Hz as the battery charge increased. In the other tests a resonant frequency increased from about 2000 Hz to about 2400 Hz as the stated charge increased. In the figures discussed herein, the data from the first set of testing is depicted in FIGS. 7, 9, 13 and 15, and data from the second set of testing is depicted in FIGS. 6, 8, 10, 12, 14 and 16.

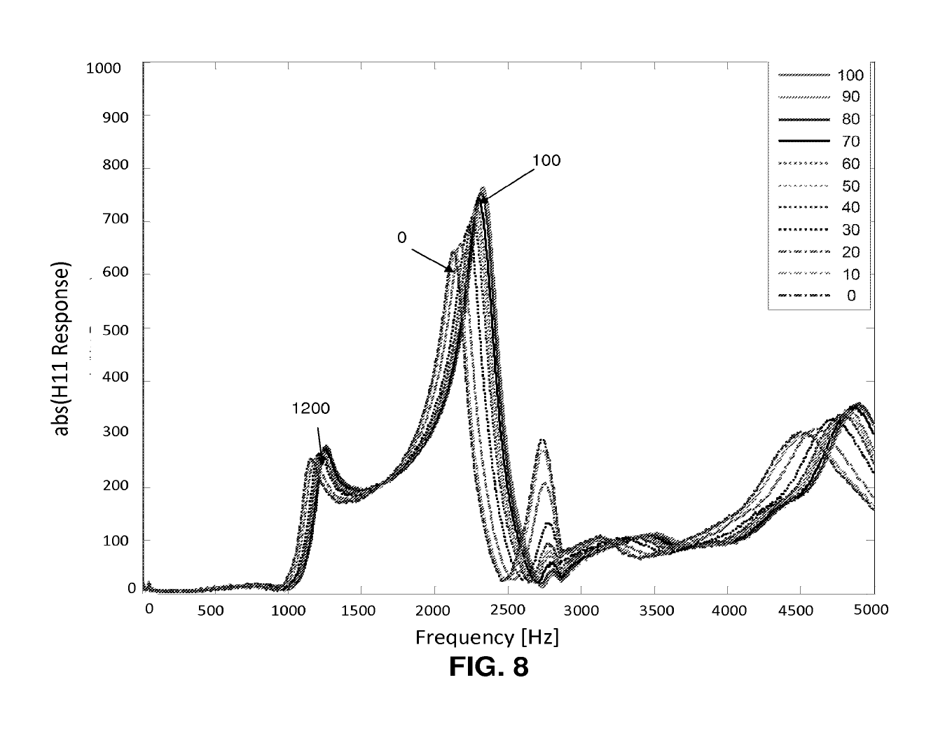

As yet another example, and as can be seen in FIG. 8, in some embodiments the sensor is placed at locations that are particularly sensitive to the state of charge. FIG. 8 shows another example where a resonant frequency between about 2700 Hz and 2800 Hz showed a significant response with relatively little charge in the battery, and yet almost no response when our battery was fully charged. Therefore, yet some embodiments pertain to detecting changes in vibrational characteristics that pertain to the measurement of phenomenon related to narrow ranges of cell charge, as opposed to other embodiments that pertain to phenomenon measured from 0 to 100 percent of cell charge.

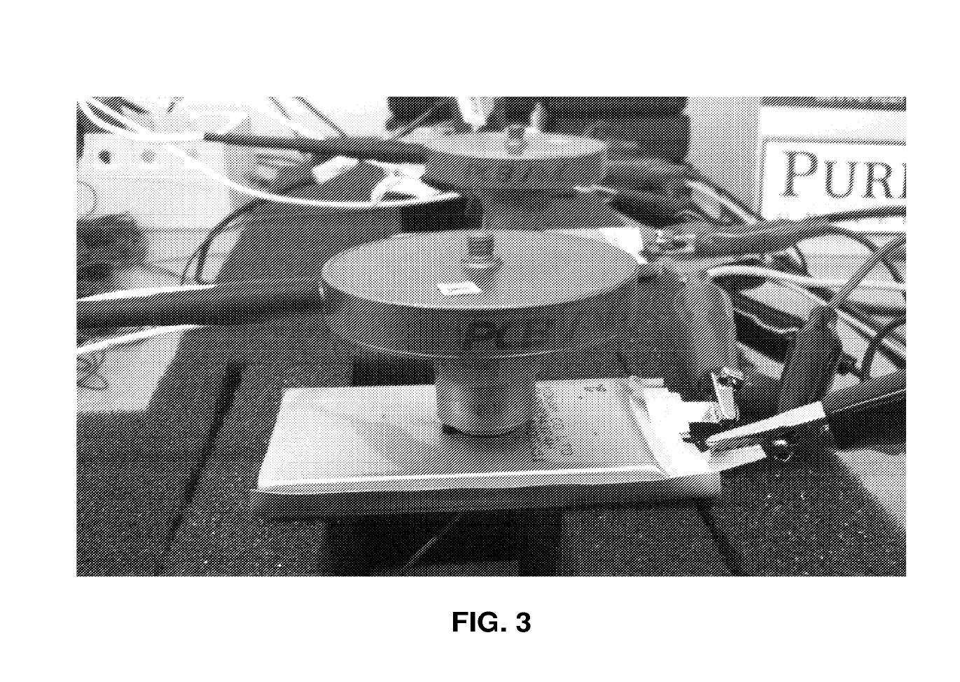

FIG. 3 shows an example battery cell that was tested. An accelerometer was attached to the top of the cell and a piezo-stack actuator was used to introduce a vibration excitation adjacent to the accelerometer. The system was swept from 1 Hz to 5000 Hz over a 2-second test period. The spectrum was then measured by the accelerometer for different states of charge. Although the use of a vibratory sweep is shown and described, it is understood that the invention is not so limited, and contemplates those embodiments in which discrete frequencies are excited, or narrow ranges of frequencies are excited, and further those excitations that are characterized by a particular wave shape (such as sign, square, triangular, or sawtooth waves to name a few), and further those embodiments in which the vibratory inputs are random (either narrowband or broadband).

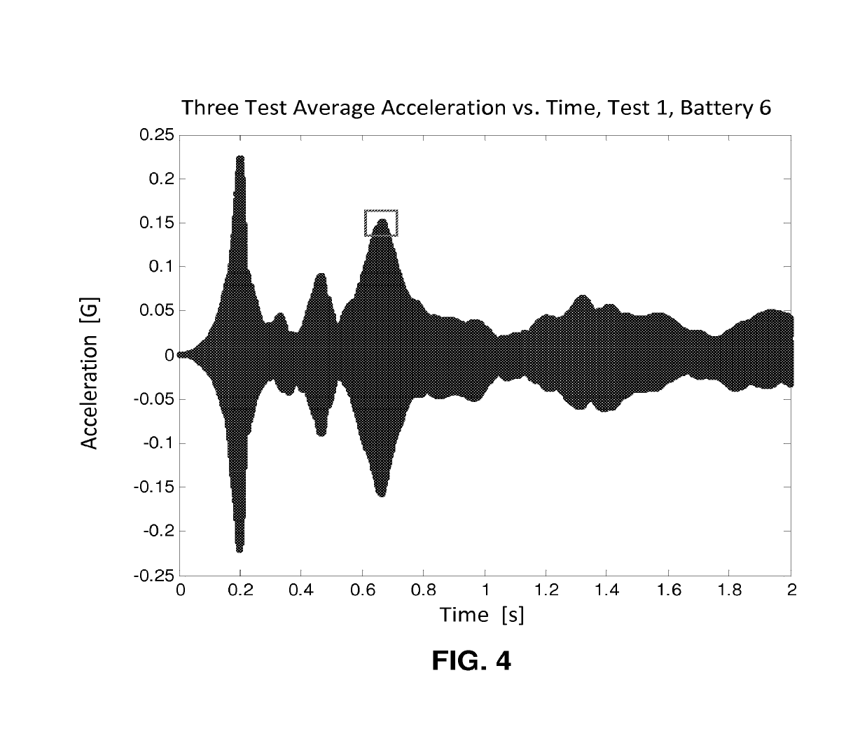

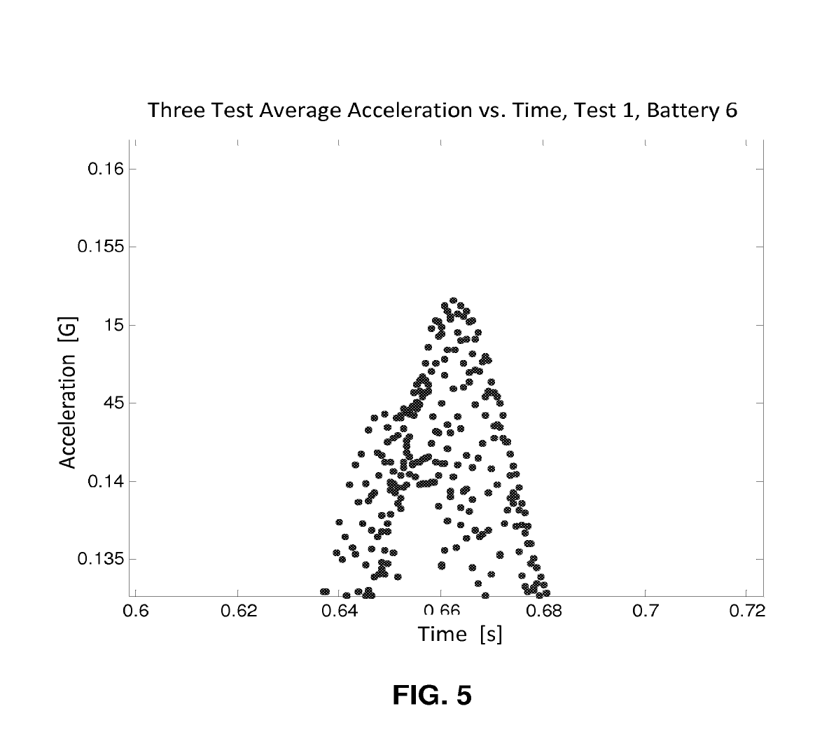

Acceleration data was collected as a function of time and is shown in FIG. 4. The data presented is the average of three tests run at the same state of charge. The solid nature of the plot is the result of many data points overlapping, causing a “filling” of the graph. A smaller region of the graph (indicated by a red square in FIG. 4) is expanded in FIG. 5 to illustrate the individual data points. Various embodiments of the present invention include different means of filtering the measured responses to remove noise. In some embodiments Fourier transforms are used to analyze the data as a response plotted against frequency. However, it is understood that the present invention is not so limited, and other embodiments pertain to data reduction methods that do not include the use of a Fourier decomposition.

In alternate embodiments the vibrational data is analyzed in terms of amplitude response and/or phase response in the frequency domain.

The data can be processed to obtain, or at least estimate, the frequency response of the system. Example frequency response estimators include H₁ and H₁₁ frequency response estimators, the H₁₁ estimator being a type of frequency response estimator where the response is applied and measured at the same point. The H₁ estimator is generally found by taking the cross power spectrum divided by the input autopower spectrum. The H₁₁ frequency response function is generally defined as the spectral displacement divided by the spectral force, where displacement is measured at the same place that the force is applied. These estimators may be available in various software packages, such as Matlab. One step to finding this response can be to calculate a Fourier transform (e.g., a Fast Fourier Transform (FFT)) of the measured acceleration and applied force. The ratio of the conjugate of the input force FFT multiplied by the output acceleration FFT, and the conjugate of the input force FFT multiplied by the input force FFT, are both calculated. H₁ is summarized in the following equation, where * stands for conjugate:

$${H}_{1} = \frac{{Sx}_{1} {y}_{1}}{{Sx}_{1} {x}_{1 }} = \frac{{F}^{*} A}{{F}^{*} F} = \frac{{FFT [ f ( t ) ]}^{*} \times FFT [ a ( t ) ]}{{FFT [ f ( t ) ]}^{*} \times FFT [ f ( t ) ]} \qquad ( 1 )$$

H₁₁ is summarized in the following equation:

H₁₁(jω)=X₁(jω)/F₁(jω)

The result of the described calculations using the data from FIG. 4 is given in FIG. 6.

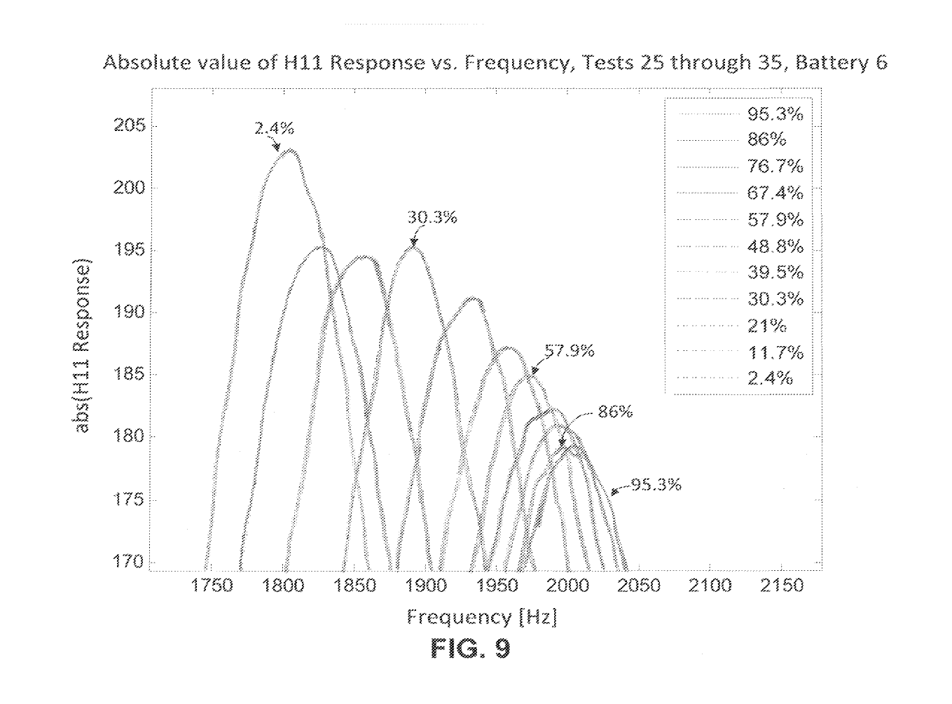

FIG. 7 shows the variation in the H₁₁ response as a function of frequency for a variable state of charge, from near 0 Hz to 5000 Hz. Distinct resonant peaks can be seen around 1900 Hz and again around 3300 Hz. For each of these two resonances, the resonant peak shifts toward higher frequency as the battery charge increases. Zooming in to the first set of peaks (FIG. 9), note that the peak in the spectrum shifts from right to left as the state of charge decreases and the peak height decreases with increasing state of charge.

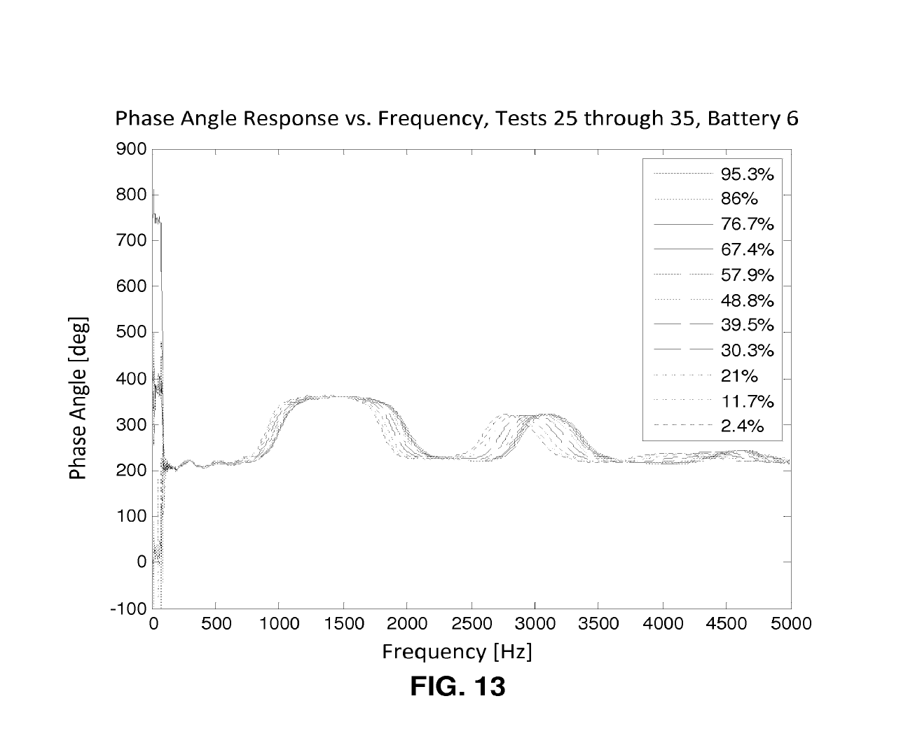

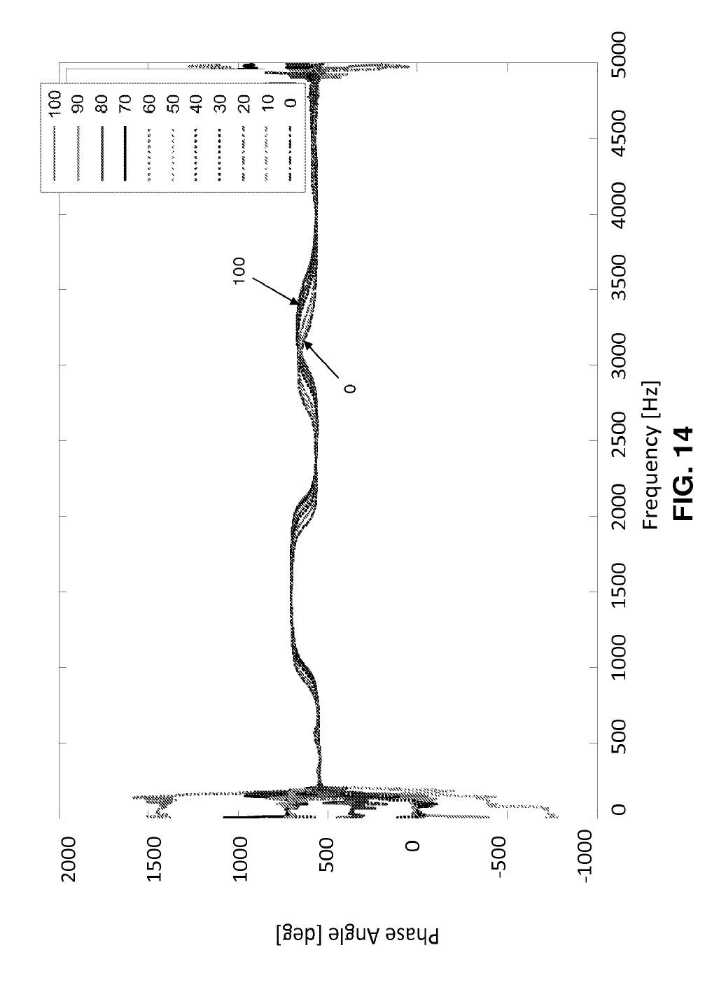

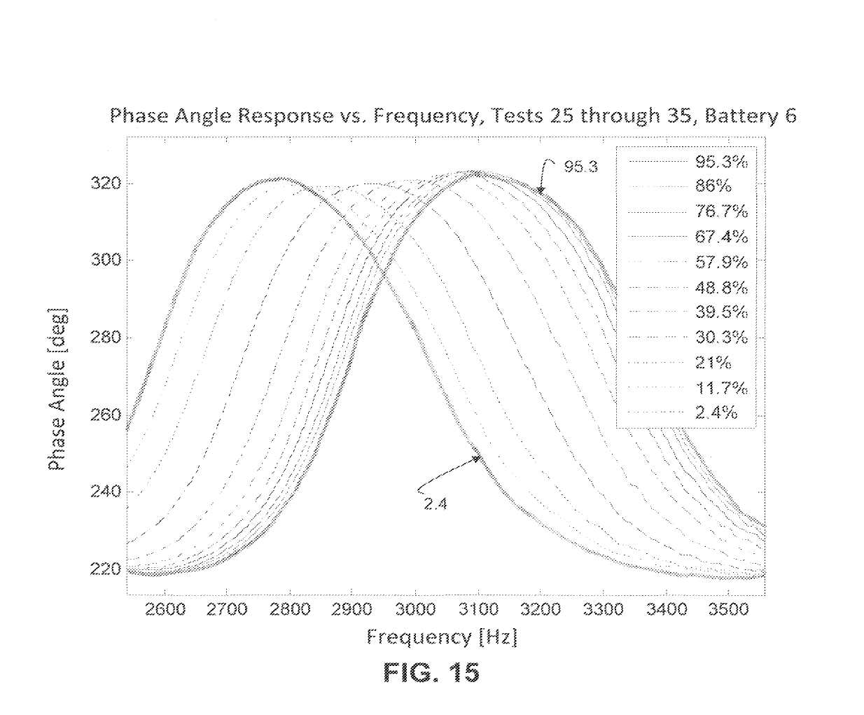

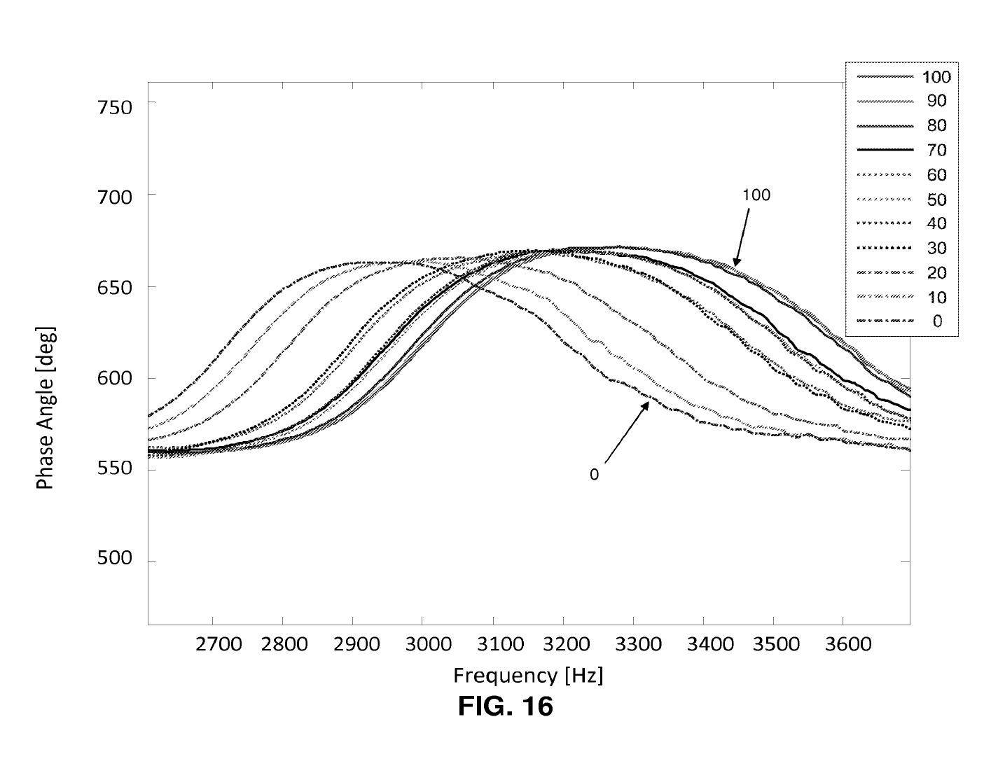

Another potential signal response is the phase angle of the H₁₁ response. The phase angle can be directly calculated using various computing programs, such as the ‘angle’ function in Matlab. The phase angle response for the data shown in FIG. 7 is shown in FIG. 13 and FIG. 15. The phase angle response for the data shown in FIG. 8 is shown in FIG. 14 and FIG. 16. The raw, calculated phase angle responses were adjusted in multiples of 360 deg., and the resultant plots are shown overlaid in FIGS. 13 and 14. The phase shift near 3000 Hz is depicted more closely in FIG. 15. It can be seen that at a first frequency band proximate to 2750 Hz and at a second band proximate to 3150 Hz that there is significant change in the phase response between the input excitation and the measurement as a function of the state of charge of the battery.

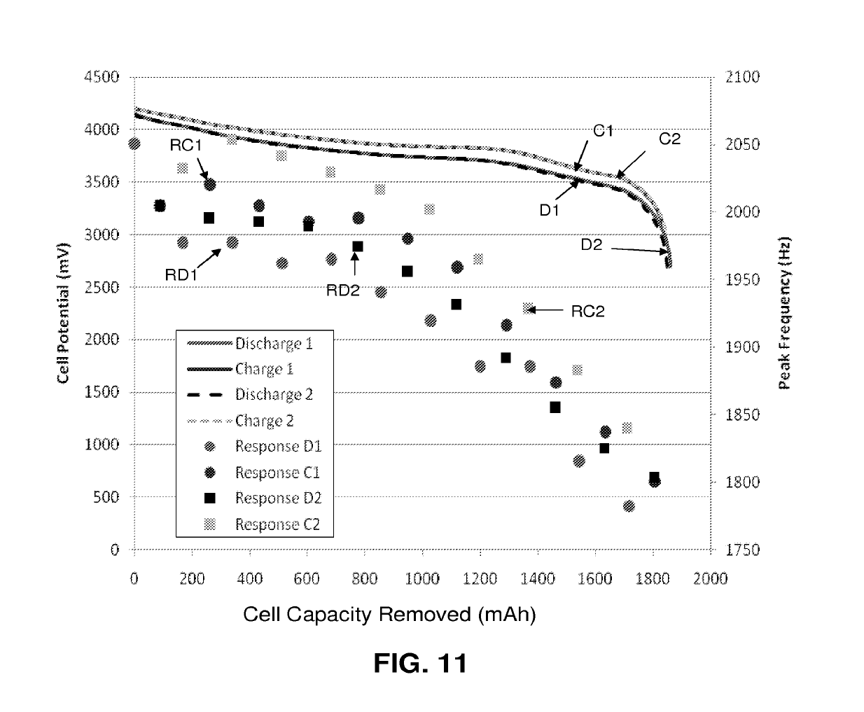

FIG. 11 depicts data from battery testing conducted according on one embodiment. The lower data sets in FIG. 11 (Response D1 (RD1), Response C1 (RC1), Response D2 (RD2), and Response C2 (RC2)) show a cross plot of the cell capacity removed in terms of milliamp hours vs. peak frequency in Hz, where the peak frequency is calculated for a particular resonance and is generally a local maximum for the resonance being considered. It can be seen that from this plot that a change in cell capacity can be measured as a change in peak frequency throughout the range of the cell capacity. In some embodiments, this relationship can be approximated in a linear relationship. In yet other embodiments, this relationship is piecewise linear, such as by a change in the linear slopes proximate to about 700 milliamp hours.

A cross plot of cell capacity vs. cell potential in millivolts can be seen in the upper sets of data (Discharge 1 (D1), Charge 1 (C1), Discharge 2 (D2), and Charge 2 (C2)) depicted in FIG. 11. There is a substantial middle portion of the amp hour vs. voltage relationship that is ambiguous such as from about 600 milliamp hours to about 1200 milliamp hours.

FIG. 11 reflects that the peak frequency response can be more sensitive to the state of charge (capacity) than the cell voltage. FIG. 11 also indicates that the peak frequency response can be a more stable indication of cell capacity than cell potential—the variability in the peak frequency response data between different charge/discharge cycles is less than the variability in the cell potential data between different charge/discharge cycles.

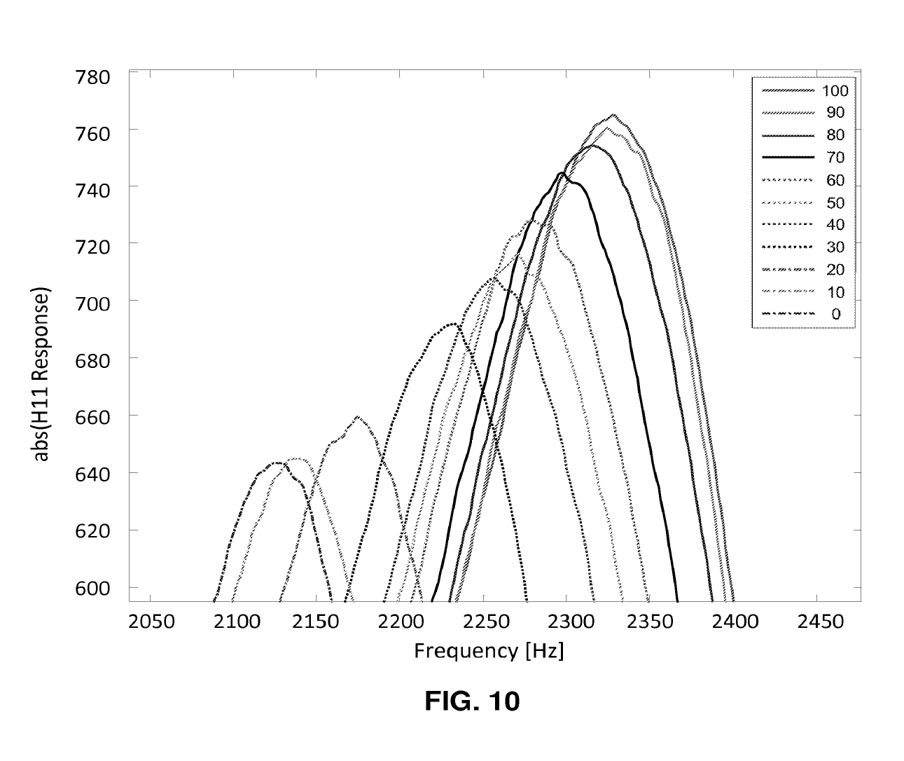

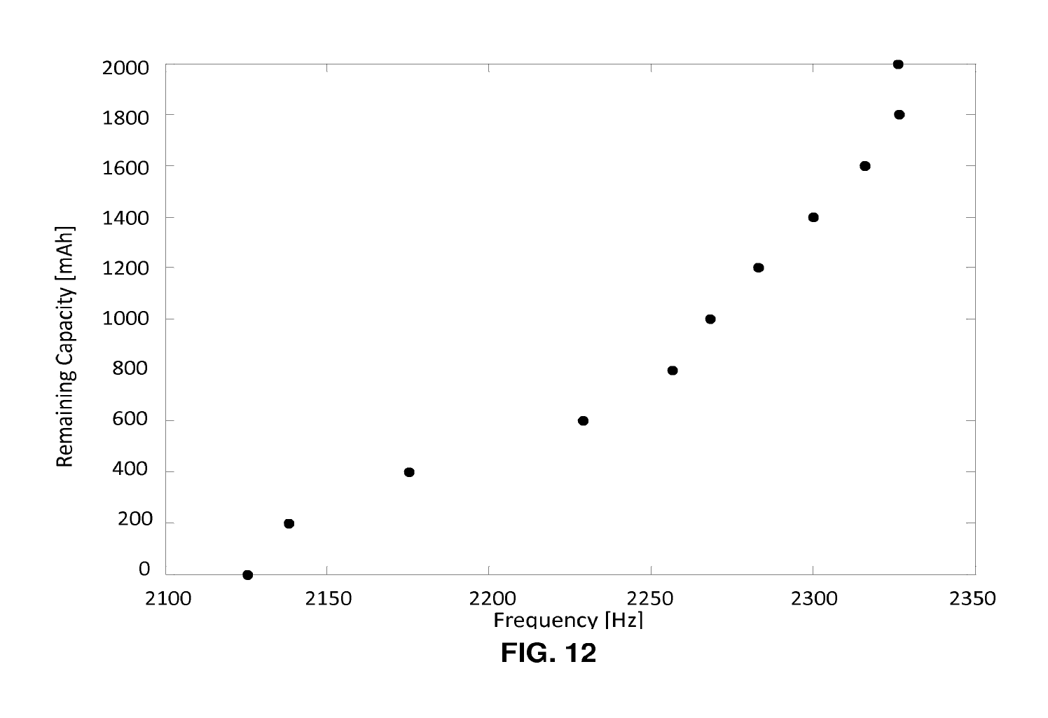

FIG. 12 represents a cross plot of cell capacity vs. peak frequency for the second set of test data (depicted in FIGS. 8 and 10). Similar to the effects noted in FIG. 11, it can be seen that in some embodiments there is a substantially monotonic relationship between the cell capacity and peak frequency. In particular, the data of FIG. 12 shows a strong change in peak frequency at the lower amounts of cell capacity. Note that since FIG. 12 depicts cell capacity remaining (e.g. zero cell capacity in FIG. 12 corresponds to a fully discharged battery) and FIG. 11 depicts cell capacity removed (e.g. zero cell capacity removed in FIG. 11 corresponds to a fully charged battery), the slope of the frequency vs. capacity curve of FIG. 12 is opposite to the slope of that same relationship in FIG. 11.

FIG. 16 represents the phase angle response for the test data represented in FIG. 8 (the second set of test data). FIG. 16 gives an enhanced view of the second group of peaks in FIG. 14 (which occur around 3000 Hz) and reveals one effect the state of charge has on the phase angle response between the input excitation and the measurement. Similar to the data shown in FIG. 15, it can be seen in FIG. 16 that there is a substantial change in phase angle in two regions, e.g., in the regions of 2850 Hz and 3350 Hz for FIG. 16 and in the regions of 2750 Hz and 3200 Hz for FIG. 15. In FIG. 16, the first region around 2850 Hz shows a general decrease in phase angle as the battery charge increases, whereas the second region shows a general increase in phase angle as the state of charge increases.

Many battery types, such lithium-ion batteries, lose their state of charge over time and various embodiments of the present invention can quickly identify the state of charge, which can have particular benefits in defense and automotive applications. In addition, this technology can also identify the state of health through monitoring of the vibro-acoustic signature throughout the charge/discharge process. Therefore, various embodiments of the inventions shown herein can predict the remaining performance of the battery (diagnostics) and identify the precursors to failure of the battery (prognostics), increasing the safety of the cell and improving the safety reputation of the battery systems (e.g., lithium battery systems) overall.

Embodiments of the present invention pertain to lithium-ion batteries. Still other embodiments pertain to other batteries or devices that have detectable mass transport. Specific embodiments have applicability with, for example, batteries used in laptop computers, electric vehicles, aircraft, and satellites. Further, the sensors and actuators described herein can be applied externally to the device undergoing measurement, or can be embedded internally within the device structure. In some embodiments, the software analyzing the measured responses is incorporated in a standalone device, whereas in other embodiments the software is embedded within other system software, such as of the overall vehicle.

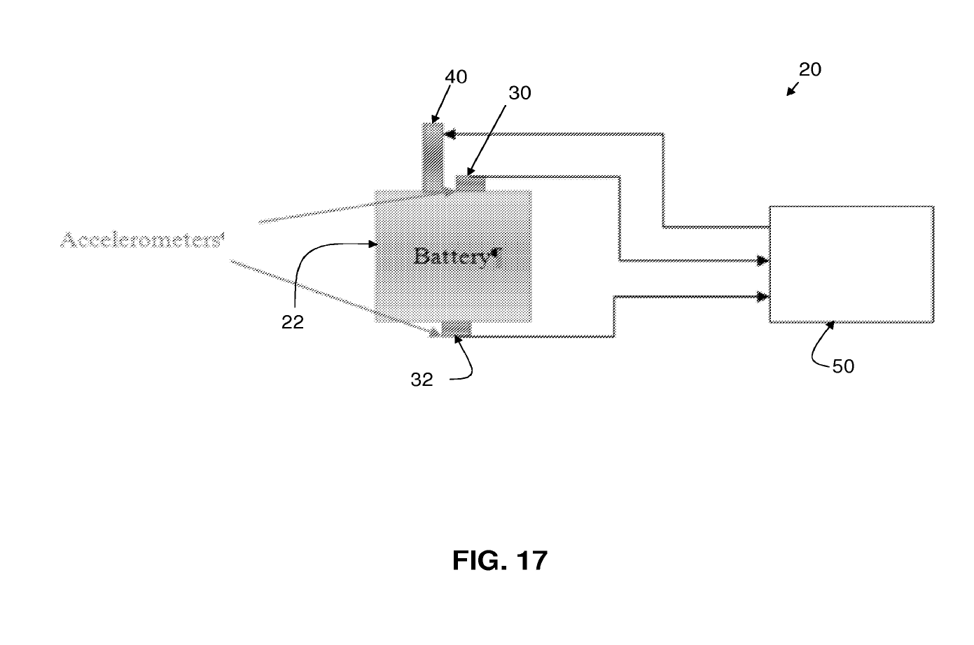

FIG. 17 shows a system 20 for measuring the state of charge of a battery according to one embodiment of the present invention. A battery 22, such as a lithium-ion battery, is connected to one or more accelerometers 30, 32. An actuator 40, such as a vibro-acoustic actuator or transducer, is also connected to the battery. In one embodiment actuator 40 provides a chirp having frequency content from about 1 to about 5000 Hz. An electronic controller 50 provides an excitation signal to actuator 40. The vibratory responses measured by accelerometers 30, 32 are provided as signals to controller 50.

In order to measure the state of charge of battery 22, controller 50 transmits a signal to actuator 40 that in turn provides a vibratory input into the structure of battery 22. In some embodiments, actuator 40 creates an acoustic signal that causes the various cathodes, anodes, and separators within battery 22 to vibrate. In yet other embodiments, actuator 40 provides a vibratory motion directly into the casing of battery 22.

In some embodiments (especially in noisy, vibratory environments such as that of a nacelle of a jet engine), no actuator may be needed. In such embodiments it is possible to measure the response of the battery cell to the externally provided vibratory input. In yet other embodiments, the ambient vibration may be utilized in the event of failure of a separate actuator placed on the battery.

The responses of battery 22 to the vibratory excitation are measured by accelerometers 30, 32. These responses are provided as electronic signals to controller 50. In some embodiments, accelerometers 30 and 32 are spatially placed apart as shown schematically in FIG. 17. In such configurations, accelerometer 30 can be used as a reference, such as when it is mechanically close-coupled to actuator 40. In such embodiments, the response of accelerometer 32 can be viewed as having been filtered relative to the response of accelerometer 30, this filtering being accomplished by the nearby structure of battery 22. Therefore, the responses of accelerometer 30 and 32 can be compared to each other, and their relative difference can be an indication of the state of charge of battery 22. In yet other embodiments, both accelerometers 30 and 32 are each considered output responses to the input from actuator 40. In such configurations, the input excitation can be considered to correspond directly to the input signal provided by controller 50. In yet other embodiments, the input excitation includes consideration of the dynamics of actuator 40 itself, and thus the input excitation used for purposes of data reduction is considered to be the input signal from controller 50 as modified by the dynamics of actuator 40.

The configuration depicted in FIG. 17 includes two accelerometers. In other embodiments of the present invention there is a single accelerometer measuring the vibratory response of battery 22 to the input excitation. Still other embodiments of the present invention are not limited to the use of an accelerometer as a sensor, and use other sensors that have sufficient response in the frequency bands of battery 22 that are most responsive to the state of charge.

Further, although the system shown in FIG. 17 includes a single actuator 40, it is understood that yet other embodiments include multiple actuators, and include multiple actuators placed at different locations on battery 22. The types of actuators and the locations of the actuators can be chosen to maximize the measurable vibratory responses of battery 22. In such embodiments, it is further understood that the excitation provided to multiple actuators can be different. In some embodiments, the input signals from controller 50 to two actuators are separated by a phase angle or time delay.

In yet other embodiments, the response of the sensors 30, 32 can be windowed in time so as to increase the probability of detecting a reflective signal. For example, the responses measured by accelerometer 30 (which in this example is located relatively close to actuator 40) may be ignored for a period of time sufficient to have the excitation signal from actuator 40 propagate across the battery structure and be reflected back, the reflected signal having been modified by the battery structure. This concept is somewhat similar to range gating in a radar system.

In yet other embodiments, the form of the excitation signal provided by actuator 40 is of any type. Although what has been shown and described herein is a broadband signal from relatively low frequencies up to 5000 Hz, it is also understood that the actuation signal may be provided only in discrete frequency bands. For example, considering the responses noted in FIG. 8, the excitation signal may be modified so as to provide actuation in a relatively narrow frequency range, such as from about 2000 Hz to about 2700 Hz.

In yet other embodiments, the input signal is established in closed loop fashion to further enhance the probability of calculating an accurate cell charge. As one example, a narrow band signal emitted within the narrow range discussed in the paragraph above can be modified based on the responses of the accelerometer to sweep through the narrow frequency range in sweeps of progressively smaller bandwidth. For example, the actuator can sweep from 2000 Hz to 2700 Hz, after which the controller calculates a peak response, or a particular phase angle. The controller can then modify the bandwidth of the swept frequencies so as to narrow the next sweep about the peak response.

Yet other embodiments of the present invention include a plurality of accelerometers to infer a mode shape within a desired frequency band. For example, the accelerometers can be placed at locations known to respond most vigorously to excitation within the aforementioned frequency band of 2000-2700 Hz. In yet other embodiments, the accelerometers are placed so as to detect the peak responses shown proximate to 2750 Hz on FIG. 8. The response as noted by this peak may be more indicative of lower states of charge, whereas measurements made at other locations on the battery (or in other frequency bands) may be more responsive to higher states of charge.

Although what will be shown and described herein pertain to measurements made on a battery, the invention is not so limited. In a broader sense other embodiments of the present invention pertain to differences in vibratory response measured in any system in which there is mass diffusion. In such systems, one area of the structure becomes more dense than another area of the structure, and those differences in mass distribution can be measured with the methods and apparatus presented herein.

While examples, representative embodiments and specific forms of the invention have been illustrated and described in detail in the drawings and foregoing description, the same is to be considered as illustrative and not restrictive or limiting. The description of particular features in one embodiment does not imply that those particular features are necessarily limited to that one embodiment. Features of one embodiment may be used in combination with features of other embodiments as would be understood by one of ordinary skill in the art, whether or not explicitly described as such. Exemplary embodiments have been shown and described, and all changes and modifications that come within the spirit of the invention are desired to be protected.

1. A method for determining the state of charge of a battery, comprising the acts of:
sensing the vibrations of a vibrating battery; and
determining the state of charge of the vibrating battery using the sensed vibrations.

2. The method of claim 1, wherein the act of determining includes determining the H₁₁ response.

3-4. (canceled)

5. The method of claim 1, wherein the act of determining includes determining the peak resonant frequency of the vibrating battery.

6. (canceled)

7. The method of claim 1, wherein the battery transfers mass during charging or discharging.

8-11. (canceled)

12. The method of claim 1, wherein the act of determining includes determining a phase shift response of the battery.

13. The method of claim 1, wherein the act of sensing includes sensing a vibratory response of the battery to an external vibratory stimulus.

14. The method of claim 13, wherein the act of determining the state of charge of the vibrating battery includes using the external vibratory stimulus.

15. The method of claim 13, further comprising generating the external vibratory stimulus.

16. The method of claim 15, wherein the act of generating includes generating chirp frequencies in the audible range.

17. The method of claim 15, wherein the act of generating includes generating chirp frequencies of at least 1 Hz to at most 5,000 Hz.

18-19. (canceled)

20. The apparatus of claim 19, wherein the calculating member calculates the H₁₁ response of the vibrational information received from the vibration sensing member.

21-22. (canceled)

23. The apparatus of claim 19, wherein the calculating member calculates the peak resonant frequency of the vibrating battery.

24. (canceled)

25. The apparatus of claim 19, further comprising a battery connected to the vibration sensing member, wherein the battery exhibit mass diffusion during charging or discharging.

26-29. (canceled)

30. The apparatus of claim 19, wherein the calculating member determines a phase shift response of the battery.

31. The apparatus of claim 19, further comprising an vibration actuator connectable to a battery.

32. The apparatus of claim 31, wherein the vibration actuator is a vibro-acoustic actuator.

33. The apparatus of claim 31, wherein the vibration actuator generates chirp frequencies in the audible range.

34. The apparatus of claim 31, wherein the vibration actuator generates chirp frequencies of at least 1 Hz to at most 5,000 Hz.

35. The apparatus of claim 19, wherein the calculating member calculates the state of charge using frequencies in the audible range.

36. The apparatus of claim 19, wherein the vibration sensing member is an accelerometer.
